(19) United States
(12) Patent Application Publication
(10) Pub. No.: US 2025/0226215 A1
(43) Pub. Date: Jul. 10, 2025

(54) SEMICONDUCTOR WAFER HAVING GAN INTERMEDIATE LAYERS FOR FORMING SEMICONDUCTOR COMPONENTS

(71) Applicant: ALLOS Semiconductor GmbH, Dresden (DE)

(72) Inventor: Atsushi NISHIKAWA, Dresden (DE)

(73) Assignee: ALLOS Semiconductor GmbH, Dresden (DE)

(21) Appl. No.: 19/096,490

(22) Filed: Mar. 31, 2025

Related U.S. Application Data
(63) Continuation of application No. PCT/EP2023/000054, filed on Aug. 27, 2023.

(30) Foreign Application Priority Data
Sep. 30, 2022 (DE) 10 2022 003 646.0

(51) Int. Cl. H01L 21/02

(52) U.S. Cl. CPC H01L 21/02458; H01L 21/02502; H01L 21/0254

(57) ABSTRACT

A semiconductor wafer for forming GaN semiconductor components having a diameter of at least 100 mm, comprising a substrate having an upper face and a lower face, wherein: the substrate is formed on the upper face of silicon. A transition layer is integrally bonded to the upper face of the substrate. A first GaN layer is integrally formed on the transition layer. The first GaN layer comprises a first GaN partial layer and a second GaN partial layer. The second GaN partial layer is formed on the first GaN partial layer. The second GaN partial layer comprises, on average, a lower number of threading dislocations than the first GaN partial layer. The first GaN partial layer has a first layer thickness and the second GaN partial layer has a second layer thickness, the second layer thickness being greater than or equal to the first layer thickness.

This nonprovisional application is a continuation of International Application No. PCT/EP2023/000054, which was filed on Aug. 27, 2023, and which claims priority to German Patent Application No. 10 2022 003 646.0, which was filed in Germany on Sep. 30, 2022, and which are both herein incorporated by reference.

### BACKGROUND OF THE INVENTION

### Field of the Invention

The invention relates to a semiconductor wafer for forming GaN semiconductor components.

### Description of the Background Art

Such semiconductor wafers primarily have a silicon substrate with an overlying buffer layer system, whereby the topmost layer of the buffer layer system comprises a GaN layer. GaN semiconductor components, in particular power transistors or LEDs, are produced on the GaN layer by means of growing and structuring of further layers.

The goal here is to form the epitaxial growth, in particular of the GaN layer or the GaN partial layers, as dislocation-free and monocrystalline as possible. In other words, the goal is to reduce the number of defects, e.g., the number of threading dislocations, as much as possible and to deposit a defect-free single crystal GaN layer in order to achieve the highest possible yield in the fabrication of semiconductor components comprising GaN or consisting of GaN.

The fabrication of layers of the buffer layer system, including the GaN layer, usually occurs with the use of vapor phase epitaxy processes, called MOVPE. The respective semiconductor layers are produced in this respect by means of deposition from the gas phase.

To produce the GaN layer from the gas phase, organic carrier gases such as, e.g., trimethylgallium ((CH3)3Ga) and ammonia (NH3) are used with the addition of hydrogen as a carrier gas in the growth of gallium nitride, whereby the reaction can be described by the reaction formula:

(CH₃)₃Ga+NH₃→GaN(solid)+₃CH_{4(gas)}.

Due to the presence of large quantities of carbon and hydrogen, small quantities of hydrogen and carbon are also unintentionally and unavoidably incorporated into the semiconductor crystal, i.e., into the GaN layer.

Whereas hydrogen can be removed by annealing in an inert gas atmosphere or in a vacuum in order, e.g., not to passivate the acceptors required for p-type conduction, the unavoidable and unintentional incorporation of carbon caused by the process leads to a p-type doping or to an increase in the residual conductivity.

Despite elaborate procedures to avoid all impurities resulting from the use of devices and starting materials necessary for the fabrication of the GaN layer, such as, e.g., metal organics, unintentional and unavoidable impurities such as oxygen are found in the GaN layer.

Processes for the fabrication of GaN layers are known from DE 10 2006 008 929 A1, EP 2 767 620 A1 (which corresponds to US 2015/0357419, which is incorporated herein by reference), DE 102 56 911 A1, US 2006/0281284 A1, and US 2013/0087762 A1.

### SUMMARY OF THE INVENTION

Against this background, the object of the invention is to provide a device which advances the prior art.

According to an example of the invention, a semiconductor wafer for forming GaN semiconductor components is provided, whereby the semiconductor wafer has a diameter of at least 100 mm. The semiconductor wafer can also have, for example, a diameter of 150 mm or 200 mm or 300 mm or 450 mm.

Furthermore, the semiconductor wafer has a substrate with an upper face and a lower face, whereby the substrate is formed of silicon on the upper face.

Furthermore, a transition layer is integrally bonded to the upper face of the substrate. A formed first GaN layer is arranged on the transition layer in an integral manner.

The first GaN layer comprises a first GaN partial layer and a second GaN partial layer, whereby the second GaN partial layer is formed on the first GaN partial layer.

The second GaN partial layer has on average a lower number of threading dislocations than the first GaN partial layer.

Furthermore, the first GaN partial layer has a first layer thickness and the second GaN partial layer has a second layer thickness, whereby the second layer thickness is greater than or equal to the first layer thickness.

The semiconductor wafer comprises a substrate, whereby the substrate comprises a single layer or consists of a single layer or, according to an example, the substrate comprises or consists of a plurality of layers arranged in a stack.

It should be noted that in the case of the substrate, a single crystal silicon layer is formed on the upper face. In an example, only the upper face is formed of a single crystal layer. The thickness of the uppermost single crystal layer can comprise a thickness in a range from 10 nm to 100 μm. Preferably, the entire surface comprises or consists of a single crystal layer.

In an example, the entire substrate can be formed of silicon, i.e., of one single crystal silicon layer.

The crystal orientation of the single crystal layer can be either <100> or <111>. It is understood, however, that the single crystal layer may also have other crystal directions, in particular a <110> or <011> or <001> direction.

It should be noted that the term “on average” may refer to a total number of threading dislocations in relation to the entire area of the first or the entire area of the second GaN partial layer. With the above definition, the area density of threading dislocations of the second GaN partial layer determined in this way is lower than the area density of threading dislocations of the first GaN partial layer.

In other words, if the number of threading dislocations on small selected areas of the second GaN partial layer is compared to small selected areas of the first GaN partial layer, it is possible that the number of threading dislocations on the second GaN partial layer is the same or even greater than the number of threading dislocations on the first GaN partial layer.

It should also be noted that the term GaN layer or GaN partial layer may refer to a layer that comprises at least the elements Ga and N. Furthermore, it should be noted that unintentional and unavoidable impurities and intentionally introduced dopants are always included in all layers.

In an example, the GaN layer or GaN partial layer also can have, in addition to the elements Ga and N, other elements such as, for example, In and/or Al and/or further elements of main group III or main group V.

The proportion of the other elements of main group III and/or the number of elements relative to main group V can be below 10%, preferably below 5%, most preferably below 1%.

The GaN layer or the respective GaN partial layer may be formed exclusively of the elements Ga and N, whereby, however, unintentional and unavoidable impurities and intentionally introduced dopants may nevertheless be included.

It should be noted that the aforementioned layers, comprising at least the transition layer and the first GaN layer, are part of a semiconductor buffer layer sequence. The purpose of the semiconductor buffer layer sequence, as mentioned at the beginning, is to provide a GaN layer that is as defect-free as possible in order to be able to produce GaN semiconductor components.

An advantage of constructing a GaN layer from a plurality of, i.e., at least two, GaN partial layers is that the quality of the uppermost GaN partial layer improves in comparison to a GaN layer comprising or consisting of a single GaN partial layer.

One reason for the improvement in the layer quality of the GaN layer is, among other things, a reduction in the number of threading dislocations.

Another advantage is that in the second GaN partial layer, compared to the first GaN partial layer, the area of the majority of the crystallites increases. This particularly reduces the number of threading dislocations. The considered area of the crystallites is formed in each case parallel to the respective layer surface and is hereinafter also referred to as the lateral area.

In other words, the average size of the crystallites in the second GaN partial layer is increased compared to the average size of the crystallites in the first GaN partial layer. The term “average size of the crystallites” is understood here to mean the arithmetic mean, i.e., the total of the lateral areas divided by the number of crystallites.

Investigations have shown that the differences between the two GaN partial layers can be generated by a change in growth conditions. At least one deposition parameter is changed in the MOVPE system between the two GaN partial layers, i.e., at the point where an interface forms between the two GaN partial layers. It is understood in this regard that the change in the modified deposition parameter is greater than the inaccuracy of the respective deposition parameter brought about by the system conditions.

The extent of the parameter change or the lower limit for the parameter change can be at least twice or at least ten times or at least fifty times the inaccuracy of the parameter as specified by the control system in MOVPE. It is understood that if a plurality of deposition parameters is changed, the above statements apply to each of the changed deposition parameters.

The first GaN partial layer and the second GaN partial layer can have the same stoichiometry.

The difference in the stoichiometry between the two GaN partial layers can be less than 2% relative to the elements of main group III and the difference in the stoichiometry is less than 2% relative to the elements of main group V.

The difference in the curvature of the semiconductor wafer during deposition of the first GaN partial layer and the second GaN partial layer can be less than 5 km⁻¹. In other words, both layers, the first GaN partial layer and the second GaN partial layer, exert the same or approximately the same stress on the substrate.

The first GaN partial layer can be almost or completely stress-free during deposition and/or immediately after deposition, i.e., neither compressively nor tensilely strained.

The second GaN partial layer can be almost or completely stress-free during deposition and/or immediately after deposition, i.e., neither compressively nor tensilely strained.

The extent of the wafer curvature can be independent of the diameter of the semiconductor wafer to a first approximation.

The first GaN partial layer can have a first lattice constant and the second GaN partial layer can have a second lattice constant. Preferably, the first lattice constant is the same as the second lattice constant. In another refinement, the difference between the two lattice constants is less than 1% or less than 0.5% or less than 0.3%.

The second GaN partial layer can be integrally formed on the first GaN partial layer.

A bonding layer can beca formed between the first GaN partial layer and the second GaN partial layer. Preferably, the lattice constant of the bonding n be is the same as the lattice constant of the first GaN partial layer and/or the same as the lattice constant of the second GaN partial layer or, in another alternative, the lattice constant of the bonding layer is different from the lattice constant of the first GaN partial layer and/or from the lattice constant of the second GaN partial layer.

The thickness of the bonding layer can be in a range between 0.5 nm and 100 nm, preferably between 0.5 nm and 30 nm.

The difference of the lattice constants between the bonding layer and the first and/or second GaN partial layer can be, in each case or overall, smaller than 1% or smaller than 0.5% or smaller than 0.3%.

The ratio of the sum of threading dislocations of the second GaN partial layer to the sum of threading dislocations of the first GaN partial layer can be between 2 and 1000 or between 5 and 40. In this regard, the sum is determined from the total number of threading dislocations of the entire layer. Preferably the sum of threading dislocations is determined on the upper face of the particular GaN partial layer.

The difference in the sum of threading dislocations at the interface of the second GaN partial layer to the first partial GaN layer is between 2 and 1000 or between 5 and 40. In this regard, the interface comprises the lower face of the second GaN partial layer and the upper face of the first GaN partial layer.

The surface density of threading dislocations in the first GaN partial layer can be in a range between 2·10⁹ cm⁻² and 1·10¹⁰ cm⁻² and the surface density of threading dislocations in the second GaN partial layer is in a range between 1·10⁷ cm⁻² and 1·10⁹ cm⁻².

The surface density of threading dislocations on the lower face in the first GaN partial layer can be greater than 5·10¹⁰ cm⁻². Furthermore, the surface density of threading dislocations on the upper face of the first GaN partial layer can be in a range between 2·10⁹ cm⁻² and 1·10¹⁰ cm⁻² and the surface density of threading dislocations on the upper face of the second GaN partial layer can be in a range between 1·10⁷ cm⁻² and 1·10⁹ cm⁻².

The first GaN partial layer, in contrast to the second GaN partial layer, can have a greater total number of threading dislocations with an oblique course. It should be noted that the term “oblique course” describes the course of the threading dislocations within the particular GaN partial layer deviating from a perpendicular direction, i.e., deviating from the direction of the normal to the upper face of the particular GaN partial layer.

It is understood here that the course of the threading dislocations within the respective GaN partial layer has both perpendicular or, to a first approximation, perpendicular sections and that the course of the threading dislocation only assumes an oblique course with increasing length. It is desirable here for the oblique course of the threading dislocations to be as horizontal as possible, i.e., parallel to the upper face of the respective GaN partial layer.

In an example, 50% or at least 80% of the threading dislocations in the first GaN partial layer can have an oblique course. In a refinement, the dislocation angle is greater than 10° or 30° or 50°.

The step angle in the first GaN partial layer can be greater than 50° or greater than 30° for the oblique threading dislocations.

The ratio of the thickness of the second GaN layer to the thickness of the first GaN can be in a range between 1 and 100 or in a range between 1 and 10 or in a range between 1 and 3.

The thickness of the first GaN partial layer can be in a range between 50 nm and 300 nm and/or the thickness of the second GaN partial layer is in a range between 300 nm and 5000 nm.

The first GaN layer can have a total layer thickness of at least 0.35 μm and a thickness of at most 5 μm.

As mentioned at the beginning, during vapor deposition to produce the GaN layer, carbon and oxygen are unavoidably incorporated during the growth of the GaN layer due to the devices and starting materials required for the fabrication of the GaN layer by means of MOVPE. The type of incorporation is also referred to as unintentional incorporation. It should be noted here that MOVPE is one possible and common method for the fabrication of GaN layers. In particular, GaN layers can also be produced using processes such as MBE or LPE or HVPE.

Studies have shown that by changing the growth conditions from the deposition of the first GaN partial layer to the second GaN partial layer, the amount of unintentional incorporation of carbon and oxygen changes.

Both the first GaN partial layer and the second GaN partial layer can have an unintentional and unavoidable, i.e. as explained above, carbon concentration inevitably generated by the deposition process. The carbon concentration in this regard in the first GaN partial layer is greater than in the second GaN partial layer.

In other words, at least one deposition process parameter in the fabrication of the first GaN partial layer is different from one of the deposition process parameters for the fabrication of the second GaN partial layer, whereby as a result the second GaN partial layer can have a higher unintentional and unavoidable carbon concentration than the first GaN partial layer.

In an example, at the interface, the ratio of the unintentional and unavoidable carbon concentration between the second GaN partial layer and that of the first GaN partial layer can be in a range between 2 and 1000 or in a range between 4 and 200 or in a range between 10 and 100.

The unintentional and unavoidable carbon concentration in the first GaN partial layer can be constant or decreases in the direction towards the second GaN partial layer.

In the first GaN partial layer, the unintentional and unavoidable carbon concentration can be constant or decreases along the distance from the interface between the transition layer and the first GaN partial layer to the interface between the first GaN partial layer and the second GaN partial layer.

The unintentional and unavoidable carbon concentration in the first GaN partial layer can be in a range between 1·10¹⁷ cm⁻³ and 5·10¹⁸ cm⁻³ and the unintentional and unavoidable carbon concentration in the second GaN partial layer an be in a range of 5·10¹⁵ cm⁻³ and 5·10¹⁶ cm⁻³.

Both the first GaN partial layer and the second GaN partial layer can have an unintentional and unavoidable oxygen concentration, i.e., as explained above, inevitably generated by the deposition process. The oxygen concentration in the first GaN partial layer can be greater than in the second GaN partial layer.

In other words, at least one deposition process parameter in the fabrication of the first GaN partial layer differs from one of the deposition process parameters for the fabrication of the second GaN partial layer, whereby as a result the second GaN partial layer has a higher unintentional and unavoidable oxygen concentration than the first GaN partial layer.

In an example, at the interface, the ratio of unintentional and unavoidable oxygen concentration between the second GaN partial layer and the first GaN partial layer can be in a range between 2 and 5000 or in a range between 4 and 200 or in a range between 10 and 100.

The unintentional and unavoidable oxygen concentration in the first GaN partial layer can be constant or decreases in the direction towards the second GaN partial layer.

The unintentional and unavoidable oxygen concentration in the first GaN partial layer can be constant or decreases along the distance from the interface between the transition layer and the first GaN partial layer to the interface between the first GaN partial layer and the second GaN partial layer.

The unintentional and unavoidable oxygen concentration in the first GaN partial layer can be in a range between 2·10¹⁷ cm⁻³ and 5·10¹⁸ cm⁻³ and the unintentional and unavoidable oxygen concentration in the second GaN partial layer can be in a range of 1·10¹⁵ cm⁻³ and 1·10¹⁷ cm⁻³.

The density of threading dislocations in the first GaN partial layer can be at least 2 times and at most 1000 times greater than the density of threading dislocations in the second GaN partial layer.

A plurality of patches integrally formed with the upper face and containing oxygen can be integrally formed on the upper face of the silicon layer of the substrate. As a result, the oxide patches can be formed on the upper face of the silicon layer and below the transition layer.

The oxygen-containing patches can cover at least 0.005% and at most 35% of the upper face of the substrate. Alternatively, the oxygen-containing patches cover at least 5% and at most 50% of the upper face of the substrate.

It is understood that the layers can each be formed over the entire surface. In this context, the term “over the entire surface” refers to the entire surface of the semiconductor wafer. Furthermore, it should be noted that the patches is formed predominantly of silicon oxide, i.e., formed of oxide or at least comprise oxide. In other words, the oxide patches remain and are covered by the subsequent layers. In no case, however, do the oxide patches form a continuous layer on the upper face of the silicon layer.

An advantage is that, surprisingly, the patches can be used to improve the quality of the semiconductor buffer layer sequence, i.e., the GaN layers on the respective upper face. In particular, the coalescence during growth of the semiconductor buffer layer sequence can be improved.

The oxygen-containing patches can cover a minimum of 0.2% to a maximum of 20% or a minimum of 0.01% to a maximum of 30% or a minimum of 0.1% to a maximum of 25% of the upper face of the substrate and are integrally bonded to the upper face of the substrate.

The oxygen-containing patches can each have a dimension of at least 10 nm or at least 50 nm or at least 100 nm. The patches can have a wide variety of shapes in this regard.

The oxygen-containing patches can each have a dimension of at most 5 μm or at most 1 μm or at most 0.5 μm.

The oxygen-containing patches can have a thickness in a range between a monolayer and 4 nm, whereby the thickness of the monolayer is approximately 0.4 nm.

The oxygen-containing patches can comprise or consist of a silicon dioxide and/or a silicon monoxide, collectively referred to hereinafter as silicon oxide.

The silicon oxide can be formed as a naturally grown oxide. Natural oxide, i.e., silicon oxide, grows in an oxygen-containing environment.

However, it should be noted that the formation of the natural oxide is accelerated in a humid environment. In this case, the density of natural oxide is below the density of a thermally grown oxide. Naturally grown oxide is understood here to be a silicon oxide that is preferably formed at room temperature, but most preferably at a temperature below 100° C. or below 200° C. The thickness of the natural oxide is between one monolayer, i.e., about 0.4 nm and 4 nm. In an example, the thickness of the natural oxide is between 1 nm and 2 nm.

A thermally grown oxide is understood here to be a silicon oxide that is preferably grown at a temperature above 500° C. The density of the thermal oxide is preferably more than 30% higher than that of the natural oxide.

The oxygen-containing patches comprise silicon oxide and oxynitride or consist of silicon oxide or consist of oxynitride.

The oxygen-containing patches are almost evenly distributed on the upper face. The term “evenly distributed” can be understood here to mean that the patches are evenly distributed over the entire surface of the semiconductor wafer. In an example, the number of patches on an area of the wafer comprising at least 20% of the total area does not deviate by more than 50% from the number of patches in a second area of the same size on the semiconductor wafer.

The semiconductor buffer layer sequence can have a thickness of at least 1 μm or at least 4 μm and a maximum thickness of 30 μm. The semiconductor buffer layer sequence can have a thickness between 0.5 μm and 10 μm or between 1.0 μm and 5 μm on the upper face.

The transition layer can comprise or consist of a layer sequence of at least two different layers.

The transition layer can have a nucleation layer formed of AlN and completely or partially covering the upper face of the substrate. The nucleation layer comprises a layer thickness of at least 5 nm and at most 50 nm. It is understood that if oxide patches are present on the upper face of the substrate, the nucleation layer at least partially covers the oxide patches.

The nucleation layer can have a plurality of holes. Preferably, the proportion of the area of the holes on the upper face of the nucleation layer, i.e., the total hole area, is between 1% and 30% of the total area of the nucleation layer.

Here, the proportion of the total hole area is calculated from the total area of the holes on the entire layer surface divided by the total area of the nucleation layer. If the transition layer on an upper face formed exclusively of the upper face of the nucleation layer, it is understood that the transition layer has the distribution and the number of holes of the nucleation layer.

The holes may be distributed equally over the entire surface of the nucleation layer to a first approximation.

The hole area relative to the entire surface of the nucleation layer can be in a range between 5% and 20%.

A masking layer comprising (Al)GaN or consisting of (Al)GaN and at least partially covering the nucleation layer can be formed on the nucleation layer.

The masking layer can have a surface area and an aluminum content between 0% and 10% relative to all the elements of main group III of the periodic table. The thickness of the masking layer has a layer thickness of at least 100 nm or at least 300 nm and at most 900 nm. In another refinement, the masking layer has a thickness between 400 nm and 600 nm.

The first GaN layer can be formed on the masking layer. The first GaN layer can be formed directly on the surface of the masking layer.

A sequence of an intermediate layer and a layer comprising a second GaN layer can be formed on the first GaN layer. It is understood that the second GaN layer comprises a first GaN partial layer or consists of a first GaN partial layer.

The second GaN layer can comprise a first GaN partial layer and a second GaN partial layer or the second GaN layer consists of a first GaN partial layer and a second GaN partial layer.

A plurality of sequences can be formed on the first GaN layer. In this case, at least 1 sequence and at most 10 sequences are formed on the first GaN layer.

The sequence can have a thickness between 0.5 μm and 10 μm or between 1.0 μm and 5 μm. The sequence can have a thickness of at least 1 μm or of at least 4 μm and at most a thickness of 30 μm

The intermediate layer comprises Al. In another refinement, the intermediate layer can comprise AlGaN or consist of AlGaN.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a cross section of a semiconductor wafer having a GaN layer, whereby the GaN layer is divided into a first GaN partial layer and a second GaN partial layer;

FIG. 2 shows a course of the lattice constant of the semiconductor wafer, shown in conjunction with the diagram in FIG. 1;

FIG. 3 shows a cross section of a semiconductor wafer with a further example of the layer arrangement; and

FIG. 4 shows a cross section of a semiconductor wafer with a detailed view of the differences in the case of threading dislocations between the first GaN partial layer and the second GaN partial layer.

### DETAILED DESCRIPTION

The layer arrangements shown below above the substrate are part of a semiconductor buffer layer sequence, whereby a so-called active layer for the fabrication of GaN semiconductor components is formed above the semiconductor buffer layer sequence, which layer is generally not to be regarded as part of the semiconductor buffer layer sequence.

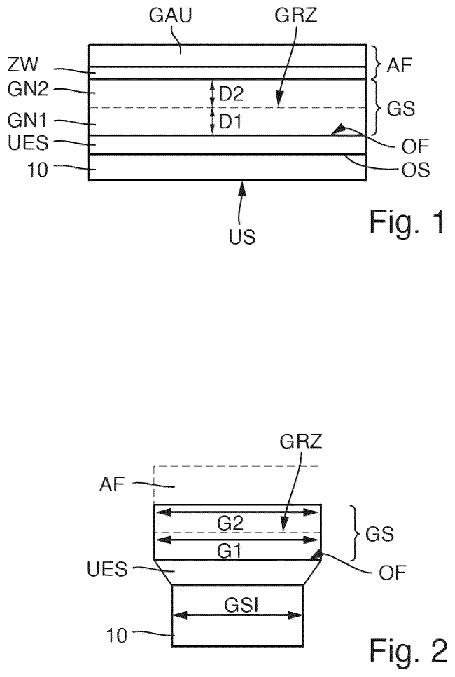

The illustration in FIG. 1 shows a cross-sectional view of a semiconductor wafer formed of a substrate 10, preferably a silicon substrate, with an upper face OS and a lower face US. Substrate 10 formed of monocrystalline silicon at least on the upper face and has a diameter of at least 100 mm.

A transition layer UES with an upper face OF is formed on the upper face OS of substrate 10, whereby the transition layer UES is integrally bonded to substrate 10. A first GaN layer GS is arranged on the upper face OF of the transition layer UES in an integral manner.

The first GaN layer GS comprises or consists of a first GaN partial layer GN1 with a thickness D1 and a second GaN partial layer GN2 with a thickness D2, whereby the thickness of the first GaN partial layer GN1 is less than or equal to the thickness D2 of the second GaN partial layer. An interface GRZ is formed between the first GaN partial layer GN1 and the second GaN partial layer GN2.

An intermediate layer ZW is formed above the first GaN layer. In the present case, the intermediate layer ZW is integrally bonded to the upper face of the first GaN layer GS.

A further GaN layer GAU is formed on the upper face of the intermediate layer ZW. The intermediate layer ZW and the further GaN layer together form a sequence AF.

In an example, a plurality of sequences AF is arranged on top of one another. It is understood that in each of the sequences AF, the further GaN layer GAU comprises or consists of a first GaN partial layer and/or a second GaN partial layer.

The illustration in FIG. 2 shows the course of the lattice constant of the semiconductor wafer, shown in connection with the illustration in FIG. 1. In the following, only the differences to the illustration in FIG. 1 are explained.

The first GaN partial layer GN1 has a first lattice constant G1. The second GaN partial layer GN2 has a second lattice constant G2. In the present case, the first lattice constant GN1 and the second lattice constant GN2 are almost the same or exactly the same.

An optional sequence of the intermediate layer ZW and the further GaN layer is shown as a dashed line, whereby the lattice constant remains the same.

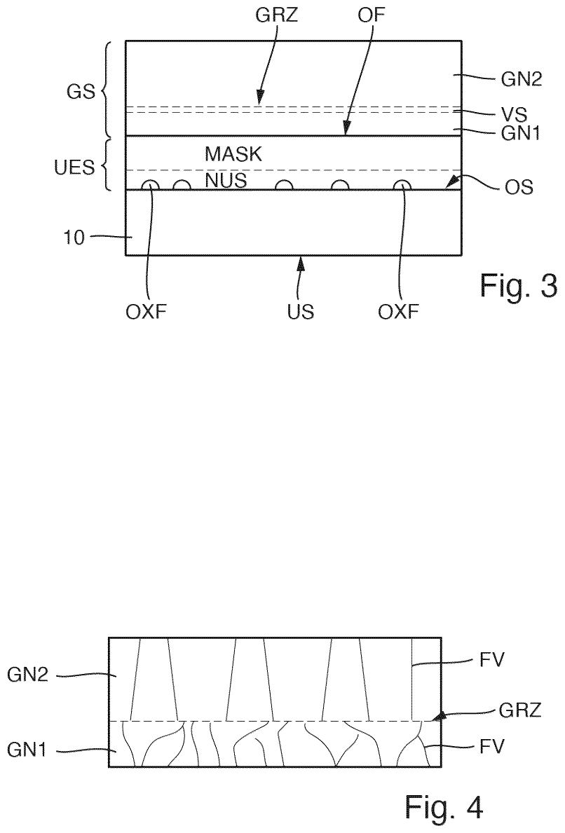

The illustration in FIG. 3 shows a cross section of a semiconductor wafer with a further example of the layer arrangement. In the following, only the differences to the previous figures are explained.

Dashed, i.e., optional, oxygen-containing patches OXF are shown on the upper face OS of silicon substrate 10. It should be noted that the patches OXF, hereinafter referred to as oxide patches, are distributed as evenly as possible on the upper face OS, but the patches OXF have irregular contours and sizes and cover at least 0.005% and at most 50% of the upper face OS of substrate 10.

The optional patches OXF are shown as part of the transition layer UES. The transition layer UES comprises a nucleation layer NUS and a masking layer MASK formed on the nucleation layer NUS. The masking layer MASK forms the upper face OF of the transition layer UES.

A thin bonding layer VS is optionally arranged at the interface GRZ between the first GaN partial layer GN1 and the second GaN partial layer GN2.

The bonding layer VS has the same lattice constant as the underlying first GaN partial layer GN1.

The illustration in FIG. 4 shows a cross section of a semiconductor wafer with a detailed view of the first GaN layer GS with differences in threading dislocations FV between the first GaN partial layer GN1 and the second GaN partial layer GN2.

On average, the second GaN partial layer GN2 has a lower number of threading dislocations FV than the first GaN partial layer GN1. The threading dislocations FV in the first GaN partial layer GN1 also usually have a more oblique shape than the threading dislocations FV in the second GaN partial layer GN2. In other words, the first GaN partial layer has a lower quality than the second GaN partial layer GN2.

The number of threading dislocations FV in the second GaN partial layer GN2 is also lower than in the first GaN partial layer GN1. As a result, the size of the crystallites in the second GaN partial layer GN2 is also significantly larger than in the first GaN partial layer GN1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor wafer for forming GaN semiconductor components having a diameter of at least 100 mm, the semiconductor wafer comprising:
a substrate having an upper face and a lower face, the substrate having silicon on the upper face;
a transition layer integrally bonded to the upper face of the substrate; and
a first GaN layer that is integrally formed on the transition layer, the first GaN layer comprising a first GaN partial layer and a second GaN partial layer,
wherein the first GaN partial layer and the second GaN partial layer each have unintentionally incorporated oxygen and/or unintentionally incorporated carbon, a concentration of unintentionally incorporated oxygen and/or unintentionally incorporated carbon in the first GaN partial layer being greater than in the second GaN partial layer,
wherein the second GaN partial layer is formed on the first GaN partial layer,
wherein the second GaN partial layer has on average a lower number of threading dislocations than the first GaN partial layer,
wherein the first GaN partial layer has a first layer thickness and the second GaN partial layer has a second layer thickness, and
wherein the second layer thickness is greater than or equal to the first layer thickness.

2. The semiconductor wafer according to claim 1, wherein a difference in a curvature of the semiconductor wafer during deposition of the first GaN partial layer and the second GaN partial layer is less than 5 km.

3. The semiconductor wafer according to claim 1, wherein the first GaN partial layer has a first lattice constant and the second GaN partial layer has a second lattice constant, and wherein the first lattice constant is the same as the second lattice constant or a difference between the first and second lattice constants is less than 1%.

4. The semiconductor wafer according to claim 1, wherein the second GaN partial layer is integrally formed on the first GaN partial layer or a bonding layer is formed between the first GaN partial layer and the second GaN partial layer, wherein the lattice constant of the bonding layer is the same as the lattice constant of the first partial layer or the lattice constant of the bonding layer is different from the lattice constant of the first GaN partial layer or from the second GaN partial layer.

5. The semiconductor wafer according to claim 1, wherein a ratio of the sum of threading dislocations of the second GaN partial layer to a sum of threading dislocations of the first GaN partial layer is between 2 and 1000 or between 5 and 40.

6. The semiconductor wafer according to claim 1, wherein a surface density of threading dislocations of the first GaN partial layer is in a range between 2·10⁹ cm⁻² and 1·10¹⁰ cm⁻², and wherein a surface density of threading dislocations in the second GaN partial layer is in a range between 1·10⁷ cm⁻² and 1·10⁹ cm⁻².

7. The semiconductor wafer according to claim 1, wherein the first GaN partial layer with respect to the second GaN partial layer, has a greater total number of threading dislocations with an oblique course.

8. The semiconductor wafer according to claim 1, wherein at least 50% or at least 80% of the threading dislocations in the first GaN partial layer have an oblique course.

9. The semiconductor wafer according to claim 1, wherein a ratio of the thickness of the second GaN partial layer to a thickness of the first GaN partial layer is in a range between 1 and 100, or in a range between 1 and 10, or in a range between 1 and 3.

10. The semiconductor wafer according to claim 1, wherein at an interface, a ratio of concentration of unintentionally incorporated carbon between the second GaN partial layer and that of the first GaN partial layer is in a range between 2 and 1000, or in a range between 4 and 200, or in a range between 10 and 100.

11. The semiconductor wafer according to claim 1, wherein at the interface, the ratio of the concentration of unintentionally incorporated oxygen between the second GaN partial layer and that of the first GaN partial layer is in a range between 2 and 5000, or in a range between 4 and 200, or in a range between 10 and 100.

12. The semiconductor wafer according to claim 1, wherein the unintentional oxygen concentration in the first GaN partial layer is in range between 2·10¹⁷ cm⁻³ and 5·10¹⁸ cm⁻³ and in the second GaN partial layer in a range of 1·10¹⁵ cm⁻³ and 1·10¹⁷ cm⁻³.

13. The semiconductor wafer according to claim 1, wherein the unintentional carbon concentration in the first GaN partial layer is in range between 1·10¹⁷ cm⁻³ and 5·10¹⁸ cm⁻³ and in the second GaN partial layer in a range of 5·10¹⁵ cm⁻³ and 5·10¹⁶ cm⁻³.

14. The semiconductor wafer according to claim 1, wherein the first GaN layer has a total layer thickness of at least 0.35 μm and of at most 5 μm.
